(19) United States
(12) Patent Application Publication
(10) Pub. No.: US 2019/0273454 A1
(43) Pub. Date: Sep. 5, 2019

(54) MOTOR CONTROL DEVICE AND MOTOR DRIVE SYSTEM

(71) Applicant: DENSO CORPORATION, Kariya-city (JP)

(72) Inventor: Tomohiro SAKURAI, Kariya-city (JP)

(21) Appl. No.: 16/414,106

(22) Filed: May 16, 2019

Related U.S. Application Data
(63) Continuation of application No. PCT/JP2017/032289, filed on Sep. 7, 2017.

(30) Foreign Application Priority Data
Nov. 25, 2016 (JP) 2016-228960

(51) Int. Cl. H02P 6/28; G01R 19/00

(52) U.S. Cl. CPC H02P 6/28; H03M 1/12; H02P 2207/05; G01R 19/0092

(57) ABSTRACT

A motor control device for performing sine-wave drive of a motor includes a first physical quantity detection unit, a second physical quantity detection unit, an A/D converter, and a conversion operation control unit. The first physical quantity detection unit outputs a current detection signal according to a terminal voltage of a single shunt resistor in which a three-phase current of the motor flows. The second physical quantity detection unit outputs a physical quantity detection signal corresponding to a physical quantity related to the drive of the motor. The A/D converter performs an A/D conversion of each of the current detection signal and the physical quantity detection signal. The conversion operation control unit controls an operation of the A/D converter so as to perform the A/D conversion of each of the current detection signal and the physical quantity detection signal.

### CROSS REFERENCE TO RELATED APPLICATIONS

The present application is a continuation application of International Patent Application No. PCT/JP2017/032289 filed on Sep. 7, 2017, which designated the U.S. and claims the benefit of priority from Japanese Patent Application No. 2016-228960 filed on Nov. 25, 2016. The entire disclosures of all of the above applications are incorporated herein by reference.

### TECHNICAL FIELD

The present disclosure relates to a motor control device for performing sine-wave drive of a three-phase motor and a motor drive system.

### BACKGROUND

There is a demand for sine-wave drive and sensorless control of a motor such as a brushless DC motor. To meet such a demand, it is necessary to detect currents flowing in the three phases of the motor. Techniques for detecting the currents include the so-called one-shunt current detection technique in which the three-phase currents are detected by one shunt resistor.

### SUMMARY

The present disclosure describes a motor control device and a motor drive system. The motor control device is configured to control a three-phase motor by a sine-wave drive. The motor drive system drives the motor by controlling a motor drive circuit with the motor control device.

### BRIEF DESCRIPTION OF DRAWINGS

The above and other objects, features and advantages of the present disclosure will become more apparent from the following detailed description made with reference to the accompanying drawings, in which:

FIG. 1 is a diagram schematically showing the configuration of a motor drive system according to a first embodiment;

FIG. 2 is a diagram schematically showing the duty command signal of each phase according to the first embodiment;

FIG. 3 is a timing chart schematically showing the duty command signal, a triangular wave signal, PWM signals, a voltage detection signal, and an A/D convertible region flag according to the first embodiment;

FIG. 4 is a diagram schematically showing the flow of processing by a free region detection unit and a determination unit according to the first embodiment;

FIG. 5 is a diagram schematically showing the flow of processing by a selection unit according to the first embodiment; and

FIG. 6 is a diagram schematically showing the flow of processing by a selection unit according to a second embodiment.

### DETAILED DESCRIPTION

In order to perform sine-wave drive and sensorless control of a motor such as a brushless DC motor, currents flowing in the three phases of the motor need to be detected. Techniques for detecting the currents include the so-called one-shunt current detection technique in which the three-phase currents are detected by one shunt resistor. According to the one-shunt current detection technique, it is possible to reduce the cost.

In such a motor control device for controlling the drive of the motor, it may be required to perform control in which an A/D converter acquires not only the current value of the three-phase current but also another physical quantity such as the voltage value of a power supply voltage or the detection value of a temperature sensor.

In the one-shunt current detection, A/D conversion timing may be generated based on the change timing of a gate drive signal for driving a power MOS transistor for energizing the motor. Therefore, the A/D conversion timing may not be constant, but may vary in accordance with a control waveform.

In such a case, therefore, it may be necessary to prepare a dedicated A/D converter separately from an A/D converter for detecting the power supply voltage or the like. As a result, two A/D converters may be required. However, the circuit area of a semiconductor integrated circuit for configuring the motor control device may increase and the manufacturing costs may increase.

According to an aspect of the present disclosure, a motor control device may perform sine-wave drive of a three-phase motor, and may include a first physical quantity detection unit, a second physical quantity detection unit, an A/D converter, and a conversion operation control unit. The first physical quantity detection unit may output a current detection signal according to a terminal voltage of a single shunt resistor that is provided so that a three-phase current of the motor flows through the shunt resistor. The second physical quantity detection unit may output a physical quantity detection signal corresponding to a physical quantity related to the drive of the motor. The A/D converter may perform an A/D conversion of the current detection signal and the physical quantity detection signal. The conversion operation control unit may control an operation of the A/D converter so as to perform the analog-to-digital conversion of the current detection signal and the physical quantity detection signal.

Thus, the motor control device with the above-described configuration is configured to perform the one-shunt current detection. In the one-shunt current detection, the current detection timing for detecting the three-phase current may not be constant, but may vary in accordance with the control waveform. Therefore, it may be conceivable to separately have an A/D converter for performing the A/D-conversion of the current detection signal and an A/D converter for performing the A/D-conversion of the physical quantity detection signal.

On the other hand, the motor control device according to the aspect of the present disclosure may be configured to realize the A/D conversion of both the current detection signal and the physical quantity detection signal, using the one A/D converter, by adding the following contrivance.

For example, the conversion operation control unit may include a free region detection unit, a determination unit, and a conversion operation execution unit. The free region detection unit may predict a current detection period for detecting the three-phase current, based on signal generation information used to generate a drive signal for driving the motor, and may obtain a free region of the A/D converter. The determination unit may determine whether or not the free region detected by the free region detection unit constitute an available time having a length enabling A/D conversion of the physical quantity detection signal. The conversion operation execution unit may perform the A/D conversion of the physical quantity detection signal using the free region determined as the available time by the determination unit.

In the above-described configuration, the current detection period for detecting the three-phase current may be predicted, free regions (free times) of the A/D converter may be obtained from the predicted current detection period, and the A/D conversion of the physical quantity detection signal may be performed using the free region having the length of equal to or longer than the time required for the A/D conversion of the physical quantity detection signal among the free regions. In such a configuration therefore, it is possible to obtain an excellent effect of enabling the current detection according to the one-shunt current detection technique and the detection of another physical quantity, using the one A/D converter.

Hereinafter, a plurality of embodiments of the present disclosure will be described with reference to the accompanying drawings. In the embodiments, substantially the same configurations are denoted by the same reference numerals, and their description will not be repeated.

### First Embodiment

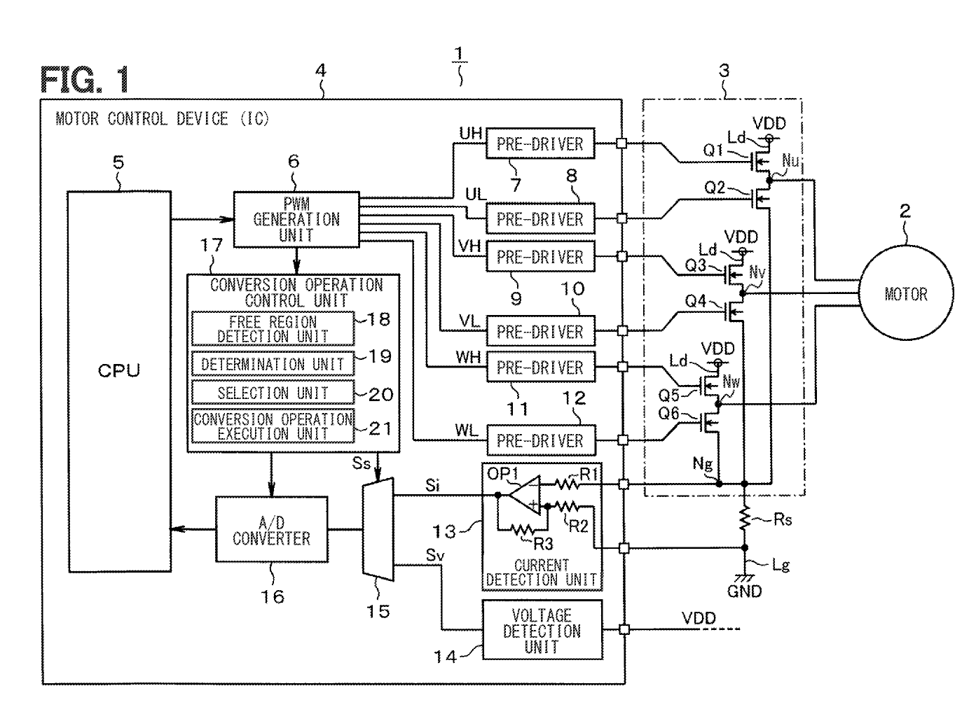

Hereinafter, a first embodiment will be described with reference to FIGS. 1 to 5.

A motor drive system 1 shown in FIG. 1 includes a motor 2 to be mounted on a vehicle, a motor drive circuit 3 for driving the motor 2, and a motor control device 4 for controlling the drive of the motor 2 by a shunt resistor Rs and the motor drive circuit 3.

The motor 2 is a three-phase brushless DC motor, and is used, for example, as a blower motor, a radiator fan motor, or the like. The shunt resistor Rs is provided so that three-phase currents of the motor 2 flow through the shunt resistor Rs. That is, in the present embodiment, the so-called one-shunt current detection in which the three-phase currents of the motor 2 are detected by the single shunt resistor Rs is performed.

The motor drive circuit 3 includes six N-channel type MOS transistors Q1 to Q6. The transistors Q1 to Q6 are connected in the form of a three-phase full-bridge between a power supply line Ld to which a power supply voltage VDD is supplied and a node Ng. The node Ng is connected through the shunt resistor Rs to a ground line Lg to which a ground potential GND as the reference potential of the circuit is supplied.

Gate drive signals outputted from the motor control device 4 are applied to the respective gates of the transistors Q1 to Q6. The gate drive signal corresponds to a drive signal for driving the motor 2. An interconnection node Nu of the transistors Q1 and Q2 is connected to the motor 2, as an output terminal of a U phase. An interconnection node Nv of the transistors Q3 and Q4 is connected to the motor 2, as an output terminal of a V phase. An interconnection node Nw of the transistors Q5 and Q6 is connected to the motor 2, as an output terminal of a W phase.

The motor control device 4 performs sine-wave drive and sensorless control of the motor 2, and is configured as a semiconductor integrated circuit (IC). The motor control device 4 includes a CPU 5, a PWM generation unit 6, pre-drivers 7 to 12, a current detection unit 13, a voltage detection unit 14, a multiplexer 15, an A/D converter 16, and a conversion operation control unit 17.

The CPU 5 controls the whole operation of the motor control device 4 in accordance with a program stored in a memory or the like (not shown). The PWM generation unit 6 generates PWM signals UH, UL, VH, VL, WH, and WL for performing the sine-wave drive of the motor 2. The PWM signals UH to WL generated by the PWM generation unit 6 are provided to the pre-drivers 7 to 12, respectively. The pre-drivers 7 to 12 output the gate drive signals obtained, for example, by level-shifting the inputted PWM signals UH to WL to the gates of the corresponding transistors Q1 to Q6, respectively.

The current detection unit 13 outputs a current detection signal Si according to the terminal voltage of the shunt resistor Rs, and includes resistors R1 to R3 and an operational amplifier OP1. The resistor R1 is connected between one terminal of the shunt resistor Rs, i.e., the node Ng and the inverting input terminal of the operational amplifier OP1. The resistor R2 is connected between the other terminal of the shunt resistor Rs, i.e., the ground line Lg and the non-inverting input terminal of the operational amplifier OP1. The resistor R3 is connected between the non-inverting input terminal and the output terminal of the operational amplifier OP1. With such a configuration, the current detection unit 13 outputs the current detection signal Si obtained by amplifying the terminal voltage of the shunt resistor Rs.

The voltage detection unit 14 outputs a voltage detection signal Sv representing the voltage value of the power supply voltage VDD obtained, for example, by dividing the power supply voltage VDD. The power supply voltage VDD is necessary for the control of the motor 2, and corresponds to a physical quantity related to the drive of the motor 2. The voltage detection signal Sv corresponds to a physical quantity detection signal corresponding to the physical quantity. In the present embodiment, the current detection unit 13 corresponds to a first physical quantity detection unit, and the voltage detection unit 14 corresponds to a second physical quantity detection unit.

The current detection signal Si and the voltage detection signal Sv are inputted to the multiplexer 15. The multiplexer 15 outputs either the current detection signal Si or the voltage detection signal Sv to the A/D converter 16, based on a selection signal provided from the conversion operation control unit 17. The A/D converter 16 performs an analog-to-digital (A/D) conversion of the current detection signal Si and the voltage detection signal Sv. Digital data outputted from the A/D converter 16 is provided to the CPU 5.

The CPU 5 acquires the current value of the three-phase current of the motor 2 based on digital data corresponding to the current detection signal Si, and acquires the voltage value of the power supply voltage VDD based on digital data corresponding to the voltage detection signal Sv. Based on the current value, the voltage value, and the like, the CPU 5 controls the operation of the PWM generation unit 6 and also the drive of the motor 2.

More specifically, based on the current value, the voltage value, and the like, the CPU 5 generates a duty command signal (duty command value) for commanding the duty of the gate drive signal for performing the sine-wave drive of the motor 2. The duty command signal of each phase is generated from a modulation rate mod and a phase 8 as shown in the following equations (1) to (3). Therefore, the modulation rate mod and the phase 8 correspond to signal generation information used to generate the drive signal for driving the motor 2.

U-phase duty command signal=mod×sin θ (1)

V-phase duty command signal=mod×sin(θ−(⅔)×π) (2)

W-phase duty command signal=mod×sin(θ+(⅔)×π) (3)

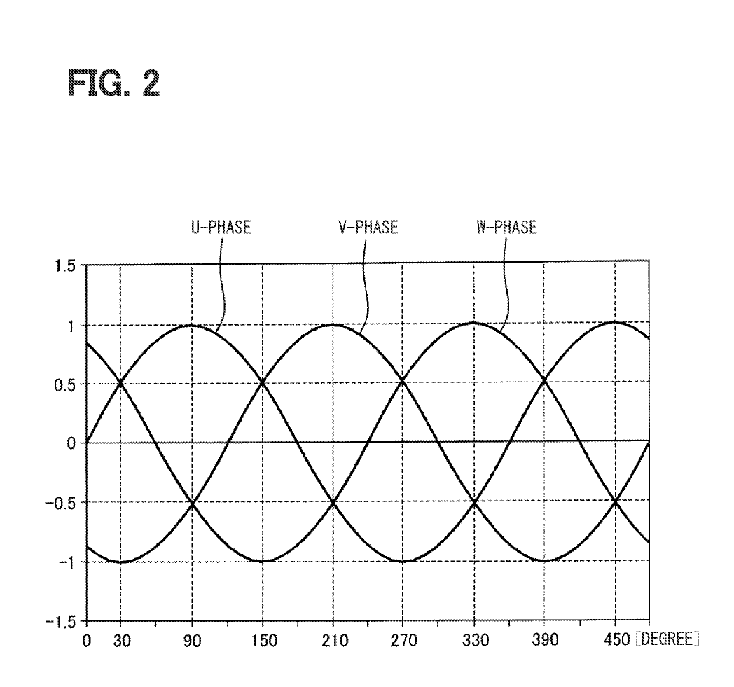

The duty command signals of the respective phases obtained based on the equations (1) to (3) are, for example, sinusoidal waveforms that are out of phase with each other by 120 degrees as shown in FIG. 2. The CPU 5 provides such a duty command signal to the PWM generation unit 6. The PWM generation unit 6 generates each PWM signal UH to WL, based on the duty command signal and a triangular wave signal obtained from the value of a PWM counter (not shown).

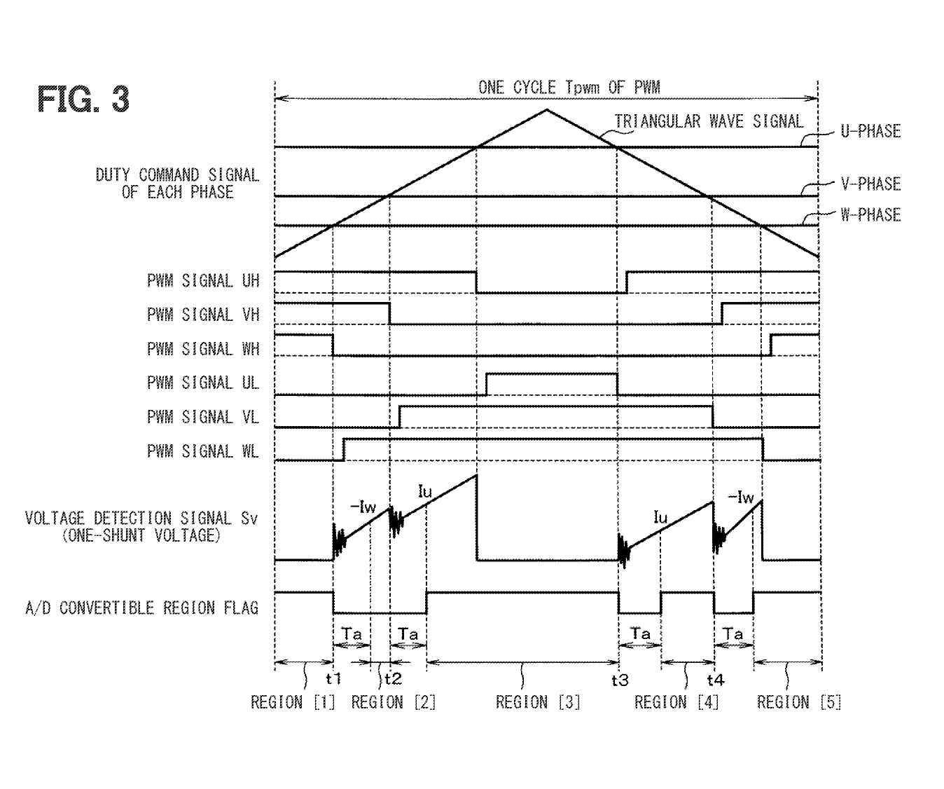

As shown in FIG. 3, the PWM generation unit 6 generates the PWM signal UH to WL inverted at timing when the duty command signal matches the triangular wave signal. However, in this case, to prevent short-circuiting of upper and lower arms, a period during which both the PWM signals UH and UL are at a low level, a period during which both the PWM signals VH and VL are at the low level, and a period during which both the PWM signals WH and WL are at the low level, i.e., dead times are needed. Accordingly, timing when the PWM signal UH to WL changes from the low level to a high level is slightly delayed from the timing when the duty command signal matches the triangular wave signal.

The conversion operation control unit 17 includes a free region detection unit 18, a determination unit 19, a selection unit 20, and a conversion operation execution unit 21. The conversion operation execution unit 21 controls the operations of the multiplexer 15 and the A/D converter 16 so that the A/D conversion of the current detection signal Si is performed at current detection timing for detecting the three-phase current. The current detection timing is, for example, the following timing.

That is, as shown in FIG. 3, in one cycle Tpwm of PWM, it is assumed that a change point t1 denotes timing when the PWM signal WH changes from the high level to the low level, a change point t2 denotes timing when the PWM signal VH changes from the high level to the low level, a change point t3 denotes timing when the PWM signal UL changes from the high level to the low level, and a change point t4 denotes timing when the PWM signal VL changes from the high level to the low level. Thus, the change points t1 to t4 are the current detection timings. The current detection timing is not constant, but varies in accordance with a control waveform.

A required time Ta required from each current detection timing to the completion of the A/D conversion of the current detection signal Si is expressed by the following equation (4). In the equation, Tdead denotes a dead time, Tring denotes a time (ringing convergence time) required until the convergence of ringing caused by the change of the gate drive signal, and Tad denotes a time (A/D conversion time) required for the A/D conversion operation.

Ta=Tdead+Tring+Tad (4)

The A/D converter 16 is occupied for the A/D conversion of the current detection signal Si for a period from each change point t1 to t4 until the elapse of the required time Ta expressed by the equation (4). The period from each change point t1 to t4 as the current detection timing until the elapse of the required time Ta corresponds to a current detection period for detecting the three-phase current.

The free region detection unit 18 obtains a period during which the A/D converter 16 is not occupied for the A/D conversion of the current detection signal Si, that is, a free region (free time) of the A/D converter 16. In this case, the free regions of the A/D converter 16 in the one cycle Tpwm of PWM are five regions [1] to [5] shown in FIG. 3. The regions [1] to [5] are expressed by the following equations (5) to (9), respectively. In the equations, times T1 to T4 denote times from the start point of the one cycle Tpwm of PWM to the change points t1 to t4, respectively.

Region [1]=T1 (5)

Region [2]=T2−(T1+Ta) (6)

Region [3]=T3−(T2+Ta) (7)

Region [4]=T4−(T3+Ta) (8)

Region [5]=Tpwm−(T4+Ta) (9)

As is obvious from the equations (5) to (9), the regions [1] to [5] can be calculated from the change points t1 to t4 as the current detection timing and the one cycle Tpwm of PWM. Accordingly, the free region detection unit 18 predicts the change points t1 to t4 as the current detection timing and also the current detection period, using the duty command signal of each phase and the cycle Tpwm, and obtains the regions [1] to [5] as the free regions of the A/D converter 16.

The free region detection unit 18 may obtain the regions [1] to [5], using the modulation rate mod and the phase 8 instead of the duty command signal of each phase. Thus, the free region detection unit 18 predicts the current detection period for detecting the three currents, based on the signal generation information used to generate the gate drive signal for driving the motor 2, and obtains the free regions of the A/D converter 16.

The determination unit 19 determines whether or not the free region detected by the free region detection unit 18 is an available time having a length enabling the A/D conversion of the voltage detection signal Sv, and indicates the determination result by an A/D convertible region flag. The length enabling the A/D conversion of the voltage detection signal Sv corresponds to the above-mentioned A/D conversion time Tad.

The A/D convertible region flag is set to the high level in a period during which a free region longer than the A/D conversion time Tad exists, and reset to the low level in the other period. For example, as shown in FIG. 3, in the case where only the region [2] of the regions [1] to [5] is less than the A/D conversion time Tad, the A/D convertible region flag is made the high level in the regions [1], [3], [4], and [5], and the low level in the other period. In the following description, “the A/D convertible region flag is made the high level” is also referred to as “the A/D convertible region flag is on”.

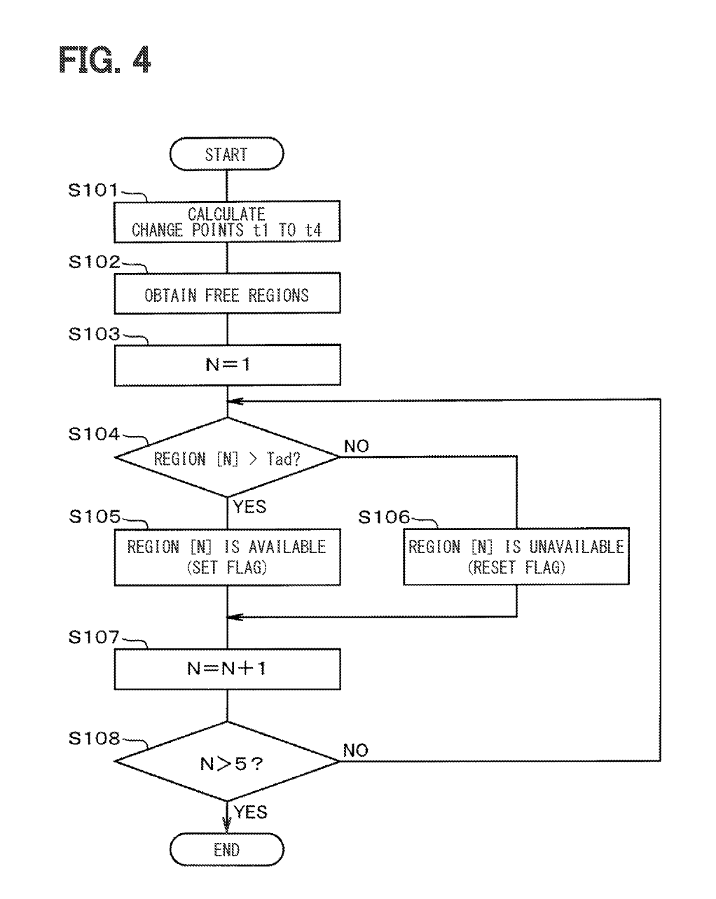

The flow of processing by the free region detection unit 18 and the determination unit 19 is shown in FIG. 4. That is, in S101, the change points t1 to t4 are calculated using the duty command signal of each phase and the like. In S102, the free regions of the A/D converter 16 are obtained using the change points t1 to t4 and the like.

In S103, the value of a variable N for specifying the number of the free region is set to “1”. In S104, it is determined whether or not the region [N] is longer than the A/D conversion time Tad. When the region [N] is longer than the A/D conversion time Tad, that is, “YES” in S104, the flow proceeds to S105.

In S105, since the region [N] has an available time, that is, is available for the A/D conversion of the voltage detection signal Sv, the A/D convertible region flag is made the high level. Alternatively, when the region [N] is equal to or shorter than the A/D conversion time Tad, that is, “NO” in S104, the flow proceeds to S106. In S106, since the region [N] has only a time less than the available time, that is, is unavailable for the A/D conversion of the voltage detection signal Sv, the A/D convertible region flag is made the low level.

After S105 or S106, the flow proceeds to S107, where the variable N is incremented. In S108, it is determined whether or not the value of the variable N exceeds “5”. When the value of the variable N exceeds “5”, that is, “YES” in S108, the processing ends. Alternatively, when the value of the variable N is not more than “5”, the flow returns to S104, and S104 to S107 are executed again.

The processing by the free region detection unit 18 and the determination unit 19 is executed every drive cycle of the motor 2, that is, every cycle of PWM. The conversion operation execution unit 21 controls the operations of the multiplexer 15 and the A/D converter 16 so that the A/D conversion of the voltage detection signal Sv is performed using the free region determined to be available in the previous PWM cycle. In other words, the conversion operation execution unit 21 controls the operations of the multiplexer 15 and the A/D converter 16 so that the A/D conversion of the voltage detection signal Sv is performed using the free region where the A/D convertible region flag is on, in the next PWM cycle.

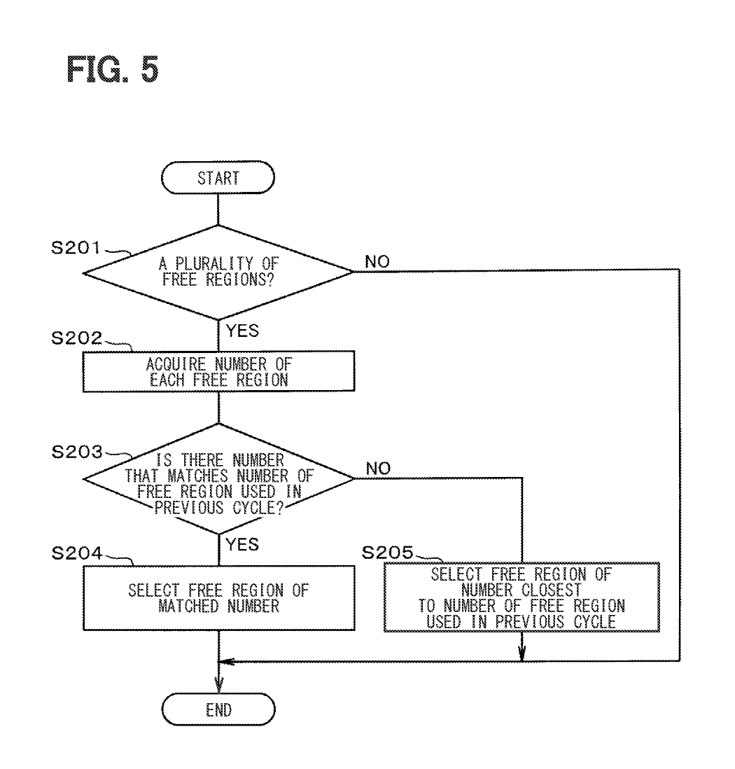

When a plurality of free regions determined as available times by the determination unit 19 exist, the selection unit 20 selects one of the plurality of free regions. In this case, the selection unit 20 performs selection of the free region so that the A/D conversion of the voltage detection signal Sv is periodically performed. The specific details of processing by the selection unit 20 are shown in FIG. 5.

As shown in FIG. 5, in S201, it is determined whether or not a plurality of free regions determined as available times (hereinafter also referred to simply as free regions) exist. When a plurality of free regions do not exist, that is, “NO” in S201, the processing ends. On the other hand, when a plurality of free regions exist, that is, “YES” in S201, the flow proceeds to S202. In S202, the number of each free region is acquired.

In S203, it is determined whether or not there is a number that matches the number of the free region used for the A/D conversion of the voltage detection signal Sv in the previous PWM cycle among the acquired numbers of the free regions. When there is a number that matches the number of the free region used in the previous cycle, that is, “YES” in S203, the flow proceeds to S204. In S204, the free region of the matched number is selected.

On the other hand, when there is no number that matches the number of the free region used in the previous cycle, that is, “NO” in S203, the flow proceeds to S205. In S205, the free region of a number closest to the number of the free region used in the previous cycle is selected. For example, in the case where the region [1] is used in the previous cycle and the regions [2], [3], and [5] exist as the free regions in this cycle, the region [2] is selected. Alternatively, in the case where the region [2] is used in the previous cycle and the regions [1], [3], and [4] exist as the free regions in this cycle, the region [1] or [3] is selected. After the execution of S204 or S205, the processing ends.

According to the above processing, the interval between the free regions selected by the selection unit 20 every cycle of PWM is approximated to the one cycle Tpwm of PWM. Therefore, the selection unit 20 selects the free region whose time from the free region used for the A/D conversion of the voltage detection signal Sv in the previous cycle is closest to the one cycle Tpwm of PWM, among the plurality of free regions. That is, the selection unit 20 selects the free region so that the A/D conversion of the voltage detection signal Sv is periodically performed.

When a plurality of free regions determined as available times by the determination unit 19 exist, the conversion operation execution unit 21 controls the operations of the multiplexer 15 and the A/D converter 16 so that the A/D conversion of the voltage detection signal Sv is performed using the free region selected by the selection unit 20.

Thus, the conversion operation control unit 17 controls the operations of the multiplexer 15 and the A/D converter 16 so that the A/D conversion of the current detection signal Si is performed at the predetermined current detection timing, and the A/D conversion of the voltage detection signal Sv is performed in a predetermined period during which the A/D conversion of the current detection signal Si is not performed.

According to the present embodiment described above, the following effects can be obtained.

The motor control device 4 according to the present embodiment performs the one-shunt current detection. In the one-shunt current detection, the current detection timing for detecting the three-phase current may not be constant, but may vary in accordance with the control waveform. Therefore, it may be conceivable to separately have the A/D converter for performing the A/D-conversion of the current detection signal and the A/D converter for performing the A/D-conversion of the detection signal of another physical quantity such as the power supply voltage.

On the other hand, the motor control device 4 realizes the A/D-conversion of both the current detection signal Si and the voltage detection signal Sv, using the one A/D converter 16. Specifically, the conversion operation control unit 17 includes the free region detection unit 18, the determination unit 19, and the conversion operation execution unit 21. The free region detection unit 18 predicts the change points t1 to t4 as the current detection timing for detecting the three-phase current and also the current detection period, based on the duty command signal used to generate the PWM signal for driving the motor 2, the cycle Tpwm of PWM, and the like, and obtains the free regions of the A/D converter 16.

The determination unit 19 determines whether or not the free region detected by the free region detection unit 18 is the available time having the length enabling the A/D conversion of the voltage detection signal Sv. The conversion operation execution unit 21 controls the operations of the multiplexer 15 and the A/D converter 16 so that the A/D conversion of the voltage detection signal Sv is performed using the free region determined as the available time by the determination unit 19.

Thus, with the above configuration, the current detection period for detecting the three-phase current is predicted, the free regions (free times) of the A/D converter 16 are obtained from the predicted current detection period, and the A/D conversion of the voltage detection signal Sv is performed using the free region having the length of equal to or longer than the time required for the A/D conversion of the voltage detection signal Sv among the free regions. Therefore, according to the above configuration, it is possible to perform the current detection according to the one-shunt current detection technique and the detection of the power supply voltage VDD as another physical quantity, using the one A/D converter 16. Therefore, according to the present embodiment, it is possible to suppress an increase in the area of the semiconductor integrated circuit for configuring the motor control device 4 and to reduce the manufacturing cost.

Further, the conversion operation control unit includes the selection unit 20 for selecting, when a plurality of free regions determined as available times by the determination unit 19 exist, one of the plurality of free regions. The selection unit 20 selects the free region so that the A/D conversion of the voltage detection signal Sv is periodically performed. The conversion operation execution unit 21 performs the A/D conversion of the voltage detection signal Sv using the free region selected by the selection unit 20. Thus, the CPU 5 can acquire the voltage value of the power supply voltage VDD at similar timing every cycle, that is, at equal intervals every cycle. Therefore, according to the present embodiment, it is possible to obtain the effect of reducing various variations in various kinds of control executed based on the power supply voltage VDD.

### Second Embodiment

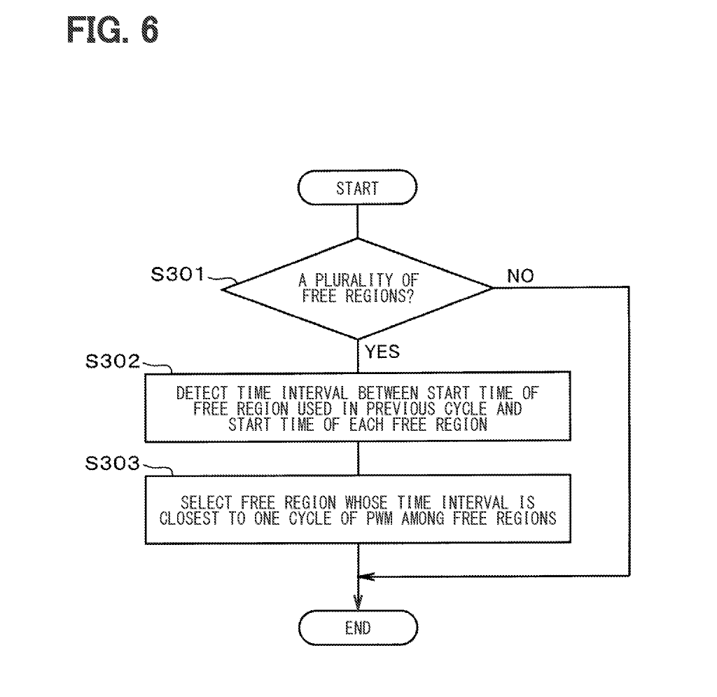

Hereinafter, a second embodiment will be described with reference to FIG. 6.

In the second embodiment, the processing content of the selection unit 20 differs from that of the first embodiment. Since the configuration is the same as in the first embodiment, the description will be made with reference to FIG. 1 as well.

S301 executed first in processing by the selection unit 20 according to the present embodiment shown in FIG. 6 has the same content as S201 according to the first embodiment shown in FIG. 5. That is, in S301, it is determined whether or not a plurality of free regions determined as available times by the determination unit 19 (hereinafter also referred to simply as free regions) exist. When a plurality of free regions do not exist, that is, “NO” in S301, the processing ends. On the other hand, when a plurality of free regions exist, that is, “YES” in S301, the flow proceeds to S302.

In S302, the time interval between the start time of the free region used for the A/D conversion of the voltage detection signal Sv in the previous PWM cycle and the start time of each free region in this cycle is detected. In S303, the free region whose time interval is closest to the one cycle Tpwm of PWM among the free regions in this cycle is selected. After the execution of S303, the processing ends.

Thus, by the processing according to the present embodiment as well, the selection unit 20 can select the free region whose time from the free region used for the A/D conversion of the voltage detection signal Sv in the previous cycle is closest to the one cycle Tpwm of PWM among the plurality of free regions, that is, can select the free region so that the A/D conversion of the voltage detection signal Sv is periodically performed. Therefore, by the present embodiment as well, the same effects as in the first embodiment can be obtained.

Further, in the present embodiment, the time interval between the start time of the free region used in the previous cycle and the start time of each free region in this cycle is measured, and the free region is selected based on the measured time interval. Therefore, the interval between the free regions selected by the selection unit 20 every cycle of PWM is further approximated to the one cycle Tpwm of PWM. Therefore, according to the present embodiment, it is possible to obtain the effect of further reducing various variations in various kinds of control executed based on the power supply voltage VDD.

### Other Embodiments

The present disclosure is not limited to the embodiments described above and shown in the drawings, and arbitrary modifications, combinations, or enhancements can be made without departing from the gist of the present disclosure.

The second physical quantity detection unit is not limited to the voltage detection unit 14 for detecting the power supply voltage VDD, and a unit for detecting a physical quantity related to the drive of the motor 2 may be employed. For example, a temperature detection unit for detecting the temperature of the motor 2 or the like using a temperature sensor may be employed. Further, a plurality of second physical quantity detection units may exist.

While, in the above embodiments, the selection unit 20 selects the free region so that the A/D conversion of the voltage detection signal Sv is periodically performed, the present disclosure is not limited thereto. For example, processing for selecting the free region having the longest time among the free regions may be adopted.

The present disclosure is not limited to the configuration for driving the motor 2 mounted on the vehicle, but can be applied to the whole configuration for performing the sine-wave drive of the three-phase motor.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A motor control device configured to perform sine-wave drive of a three-phase motor, the motor control device comprising:
a first physical quantity detection unit configured to output a current detection signal according to a terminal voltage of a single shunt resistor that is provided so that a three-phase current of the motor flows through the shunt resistor;
a second physical quantity detection unit configured to output a physical quantity detection signal corresponding to a physical quantity related to the drive of the motor;
an A/D converter configured to perform an analog-to-digital conversion of each of the current detection signal and the physical quantity detection signal; and
a conversion operation control unit configured to control an operation of the A/D converter so as to perform the analog-to-digital conversion of the current detection signal and the physical quantity detection signal, wherein
the conversion operation control unit includes
a free region detection unit configured to predict a current detection period for detecting the three-phase current based on signal generation information used to generate a drive signal for driving the motor and to obtain a free region of the A/D converter,
a determination unit configured to determine whether the free region detected by the free region detection unit has a length enabling the analog-to-digital conversion of the physical quantity detection signal, as an available time, and
a conversion operation execution unit configured to allow the A/D converter to perform the analog-to-digital conversion of the physical quantity detection signal using the free region determined as having the length as the available time by the determination unit.

2. The motor control device according to claim 1, wherein
the physical quantity related to the drive of the motor is a power supply voltage applied to the motor, and
the physical quantity detection signal is a voltage detection signal corresponding to the power supply voltage.

3. The motor control device according to claim 1, wherein
the conversion operation control unit includes a selection unit that is configured to select, when a plurality of the free regions each determined as having the length as the available time by the determination unit exist, one of the plurality of the free regions,
the selection unit performs selection of the one of the plurality of the free regions so that the analog-to-digital conversion of the physical quantity detection signal is periodically performed, and
the conversion operation execution unit allows the A/D converter to perform the analog-to-digital conversion of the physical quantity detection signal using the free region selected by the selection unit.

4. The motor control device according to claim 3, wherein
the selection unit selects, among the plurality of the free regions, one whose time from the free region used for the analog-to-digital conversion of the physical quantity detection signal in the previous cycle is closest to a drive cycle of the motor.

5. A motor drive system comprising:
a motor;
a single shunt resistor that is provided so that a three-phase current of the motor flows through the shunt resistor;
a motor drive circuit configured to drive the motor; and
the motor control device according to claim 1 and configured to control the motor drive circuit.

6. A motor control device configured to perform sine-wave drive of a three-phase motor, the motor control device comprising:
a first physical quantity detection unit coupled to a single shunt resistor that is provided so that a three-phase current of the motor flows through the shunt resistor, and configured to output a current detection signal according to a terminal voltage of the shunt resistor;
a second physical quantity detection unit configured to output a physical quantity detection signal corresponding to a physical quantity related to the drive of the motor;
an A/D converter coupled to the first physical quantity detection unit and the second physical quantity detection unit, and configured to perform an analog-to-digital conversion of each of the current detection signal and the physical quantity detection signal; and
a conversion operation controller configured to control an operation of the A/D converter so as to perform the analog-to-digital conversion of each of the current detection signal and the physical quantity detection signal, the conversion operation controller further configured
to predict a current detection period for detecting the three-phase current, based on signal generation information used to generate a drive signal for driving the motor,
to obtain a free region of the A/D converter free from the analog-to-digital conversion of the current detection signal,
to determine whether the free region has a length enabling the analog-to-digital conversion of the physical quantity detection signal, as an available time, and
to allow the A/D converter to perform the analog-to-digital conversion of the physical quantity detection signal in the free region in response to the free region being determined as having the length as the available time.
